(19) United States
(12) Patent Application Publication
(10) Pub. No.: US 2024/0365876 A1
(43) Pub. Date: Nov. 7, 2024

(54) AEROSOL-GENERATING DEVICE WITH MEANS FOR DETECTING AT LEAST ONE OF THE INSERTION OR THE EXTRACTION OF AN AEROSOL-GENERATING ARTICLE INTO OR FROM THE DEVICE

(71) Applicant: Philip Morris Products S.A., Neuchatel (CH)

(72) Inventors: Yannick BUTIN, Neuchatel (CH); Enrico STURA, Neuchatel (CH); Maxime CHATEAU, Neuchatel (CH); Denis NIZOVTSEV, Neuchatel (CH); William POIDVIN, Petit-Lancy (CH)

(73) Assignee: Philip Morris Products S.A., Neuchatel (CH)

(21) Appl. No.: 18/577,555

(22) PCT Filed: Jul. 7, 2022
(86) PCT No.: PCT/EP2022/068975

§ 371 Date: Jan. 8, 2024

(30) Foreign Application Priority Data
Jul. 12, 2021 (EP) 21184939.3

(51) Int. Cl. A24F 40/53; A24D 1/20; A24F 40/20; A24F 40/465; A24F 40/57; G01R 27/08; H05B 6/10

(52) U.S. Cl. CPC A24F 40/53; A24D 1/20; A24F 40/20; A24F 40/465; A24F 40/57; G01R 27/08; H05B 6/105

(57) ABSTRACT

An aerosol-generating device is provided for heating an aerosol-forming substrate to form an inhalable aerosol, the device including: a cavity to removably receive at least a portion of an aerosol-generating article including the substrate and an inductively heatable susceptor configured to heat the substrate; an inductive heating arrangement to generate an alternating magnetic field within the cavity for inductively heating the susceptor when the article is received in the cavity; and a control circuitry to generate power pulses for intermittently powering on the arrangement, to determine during one or more power pulses a value of at least one property of the arrangement, the value depending on an article with a susceptor being present in or absent from the cavity, and to detect at least one of the insertion or the extraction of the article into or from the cavity based on the determined value and a predetermined threshold value.

The present invention relates to an aerosol-generating device comprising a cavity and means for detecting the insertion or the extraction of an aerosol-generating article into the cavity. The invention further relates to an aerosol-generating system comprising such a device as well as to a method for detecting whether an aerosol-generating article is present in or absent from a cavity of an aerosol-generating device.

Aerosol-generating devices used for generating inhalable aerosols by heating aerosol-forming substrates are generally known from prior art. Such devices may comprise a cavity for removably receiving at least a portion of an aerosol-generating article that includes the aerosol-forming substrate to be heated. For heating the substrate, the devices may further comprise an inductive heating arrangement powered by a battery and configured to generate an alternating magnetic field within the cavity for inductively heating a susceptor that—in use of the device—is in thermal proximity or direct physical contact with substrate. The susceptor may be an integral part of the aerosol-generating article. Such devices may also comprise means for detecting whether an aerosol-generating article is present in or absent from the receiving cavity in order to enable or disable the heating process. This kind of detection may be realized by separate sensor means which continuously monitor the presence or non-presence of the article in the cavity. However, separate sensor means typically require additional assembly space in the device. Moreover, a continuous operation of the sensor is energy-consuming and, thus, may significantly reduce the operation time of the device.

Therefore, it would be desirable to have an aerosol-generating device with the advantages of prior art solutions, whilst mitigating their limitations. In particular, it would be desirable to have an aerosol-generating device providing improved means for detecting the insertion or the extraction of an aerosol-generating article into the receiving cavity of the device.

According to the present invention there is provided an aerosol-generating device for heating an aerosol-forming substrate that is capable to form an inhalable aerosol when heated. The device comprises a cavity for removably receiving at least a portion of an aerosol-generating article, wherein the article includes the aerosol-forming substrate and an inductively heatable susceptor for heating the substrate. The device further comprises an inductive heating arrangement configured to generate an alternating magnetic field within the cavity for inductively heating the susceptor of the article when the article is received in the cavity. The device also comprises a control circuitry configured to generate power pulses for intermittently powering on the inductive heating arrangement and to determine during one or more power pulses a value of at least one property of the inductive heating arrangement, the value depending on an article with a susceptor being present in or absent from the cavity. Furthermore, the control circuitry is configured to detect at least one of the insertion of an article into the cavity or the extraction of an article from the cavity based on the determined value and a predetermined threshold value, in particular based on a comparison of the determined value with a predetermined threshold value, more particularly in response to the determined value having breached a predetermined threshold value.

According to the invention it has been found that the inductive heating arrangement may be used not only for heating the substrate, but also for detecting at least one of the insertion of an article into the cavity or the extraction of an article from the cavity. Thus, the inductive heating arrangement may be used for multiple purposes. Advantageously, this enables to avoid additional assembly space for separate sensor means.

Moreover, it has been found that operating the inductive heating arrangement in a pulsed mode for the purpose of article detection advantageously reduces the power consumption and, thus, increases the overall operation time of the device as compared to other solutions.

According to the present invention detection of article insertion or article extraction is based on the fact that the insertion and extraction of the article into or from the cavity modifies at least one property, in particular at least one electrical and/or magnetic property of the inductive heating arrangement due to the susceptor becoming present at or absent from the vicinity of the inductive heating arrangement. The change of the at least one property caused by the susceptor becoming present at or absent may be due to an interaction between the field of the inductive heating arrangement and the susceptor. That is, the at least one property of the inductive heating arrangement has different values depending on whether an article with a susceptor is present in or absent from the cavity.

Yet, instead of detecting the change of the at least one property occurring when an article is inserted into or extracted from the cavity, the present invention suggest to determine a value of at least one property of the inductive heating arrangement and to detect at least one of the insertion of an article into the cavity or the extraction of an article from the cavity based on the determined value and a predetermined threshold value. In particular, the present invention suggest to compare the determined value with a predetermined threshold value which is chosen such as to reliably allow to distinguish between an article being present in the cavity and an article being absent from the cavity. Advantageously, determining a value of the at least one property and comparing the determined value with a predetermined threshold value, which does not originate from an instant measurement, makes the detection of the insertion or the extraction of an aerosol-generating article more reliable. In particular, this procedure avoids undesired false-positive or false-negative detection of the insertion or the extraction of an aerosol-generating article, for example, when an article is inserted into and extracted from the cavity only gradually or partially.

As used herein, a/the value of the at least one property of the inductive heating arrangement as determined (or to be determined) by the control circuitry may refer to an actual value of the at least one property of the inductive heating arrangement as being (instantaneously) determined by the control circuitry. The actual value of the at least one property of the inductive heating arrangement as being (instantaneously) determined by the control circuitry may be within 20% of the actual value, or within 15% of the actual value, or within 10% of the actual value, or within 5% of the real value of the at least one property of the inductive heating arrangement as being actually present in the inductive heating arrangement.

The at least one property of the inductive heating arrangement may be any property which has different values depending on an article with a susceptor being present in or absent from the cavity, that is, which has a different value in the presence of the susceptor as compared to the value in the absence of the susceptor. For example, the at least one property may be a current, a voltage, an electrical resistance, an electrical conductance, a frequency, a phase shift, a flux, and an inductance of the inductive heating arrangement.

Preferably, the property is at least one of an electrical (equivalent) resistance, an electrical (equivalent) conductance or an inductance of the inductive heating arrangement. As used herein, the term “electrical (equivalent) resistance” refers to the real part of a complex impedance defined as the ratio of the AC voltage supplied to the inductive heating arrangement to the measured AC current. Accordingly, the “equivalent resistance” may also be denoted as the resistive load of the inductive heating arrangement. Vice versa, the term “electrical (equivalent) conductance” refers to the inverse of the electrical (equivalent) resistance, that is, to the ratio of the measured current to the voltage supplied to the inductive heating arrangement. Likewise, as used herein, the term “inductance” refers to the imaginary part of a complex impedance defined as the ratio of the supplied voltage to the measured current. Inductance, generally speaking, includes the property of an electric circuit to be susceptible to exterior electromagnetic influences.

The change of at least one property of the inductive heating arrangement leading to the predetermined threshold value being breached may be due to a specific magnetic permeability and/or a specific electrical resistivity of the susceptor. That is, the susceptor within the aerosol-generating article may include a material having a specific magnetic permeability and/or a specific electrical resistivity. Preferably, the susceptor comprises an electrically conductive material. For example, the susceptor may comprise a metallic material. The metallic material may be, for example, one of aluminum, nickel, iron, or alloys thereof, for example, carbon steel or ferritic stainless steel. Aluminum has an electrical resistivity of about 2.65×10E-08 Ohm-meter, measured at room temperature (20° C.), and a magnetic permeability of about 1.256×10E-06 Henry per meter. Likewise, ferritic stainless steel has an electrical resistivity of about 6.9×10E-07 Ohm-meter, measured at room temperature (20° C.), and a magnetic permeability in a range of 1.26×10E-03 Henry per meter to 2.26×10E-03 Henry per meter.

In general, the predetermined threshold value may be a predefined function of a reference value of the at least one property of the inductive heating arrangement being (pre)determined when an aerosol-generating article comprising a susceptor is absent from the cavity. In this case, the reference value defines a clear value of the at least one property being indicative of an aerosol-generating article being absent from the cavity. In contrast, the threshold values defines a value above or below which a value of the at least one property being determined for one or more power pulses during operation of the device is indicative of an aerosol-generating article being present in the cavity, depending on whether the at least one property of the inductive heating arrangement increases or decreases, when an aerosol-generating article is inserted into the device. Accordingly, depending on whether the at least one property of the inductive heating arrangement increases or decreases, when an aerosol-generating article is inserted into the device, the function is to be chosen such that the threshold value is larger or smaller than the reference value taken when no article is present in the cavity. Likewise, the predetermined threshold value may be a predefined function of a reference value of the at least one property of the inductive heating arrangement being (pre)determined when an aerosol-generating article comprising a susceptor is present the cavity. In this case, the reference value defines a clear value of the at least one property being indicative of an aerosol-generating article being present in the cavity. In contrast, the threshold values defines a value above or below which a value of the at least one property being determined for one or more power pulses during operation of the device is indicative of an aerosol-generating article being absent from the cavity, depending on whether the at least one property of the inductive heating arrangement increases or decreases, when an aerosol-generating article is inserted into the device. Accordingly, depending on whether the at least one property of the inductive heating arrangement increases or decreases, when an aerosol-generating article is inserted into the device, the function is to be chosen such that the threshold value is smaller or larger than the reference value taken when an article is present in the cavity. In either case, the threshold value is somewhere between the value of the at least one property being measured when an article is present the cavity (reference value) and the value of the at least one property being measured when no article is present in the cavity.

The predefined function may be a linear function. That is, the threshold value may be a linear function of the reference value of the at least one property of the inductive heating arrangement being determined when an aerosol-generating article comprising a susceptor is absent from the cavity. In particular, the predetermined threshold value may correspond to a reference value of the at least one property of the inductive heating arrangement—(pre)determined when an aerosol-generating article comprising a susceptor is absent from the cavity—times a predefined scaling factor. Likewise, the threshold value may be a linear function of the reference value of the at least one property of the inductive heating arrangement being determined when an aerosol-generating article comprising a susceptor is present in the cavity. Also in this case, the predetermined threshold value may correspond to a reference value of the at least one property of the inductive heating arrangement-(pre)determined when an aerosol-generating article comprising a susceptor is present in the cavity-times a predefined scaling factor. Depending on whether the at least one property of the inductive heating arrangement increases or decreases, when an aerosol-generating article is inserted into the device, the scaling factor may be larger or smaller than 1.

Where the reference value of the at least one property of the inductive heating arrangement is (pre)determined when an aerosol-generating article comprising a susceptor is absent from the cavity, the predefined scaling factor may be in a range between 0.8 and 0.98, in particular between 0.9 and 0.95, more particularly between 0.92 and 0.94, in case the at least one property of the inductive heating arrangement decreases when an aerosol-generating article is inserted into the device. Likewise, the predefined scaling factor may be in a range between 1.02 and 1.2, in particular between 1.05 and 1.1, more particularly between 1.06 and 1.08, in case the at least one property of the inductive heating arrangement increases when an aerosol-generating article is inserted into the device. As example, in case the at least one property of the inductive heating arrangement is an electrical (equivalent) conductance of the inductive heating arrangement, the conductance decrease when an aerosol-generating article is inserted into the device. In this case, the scaling factor may be, for example, 0.94. The aforementioned scaling factors have proven to be appropriate in order to clearly distinguish between an article being absent from the cavity or being present in the cavity.

Where the reference value of the at least one property of the inductive heating arrangement is (pre)determined when an aerosol-generating article comprising a susceptor is present in the cavity, the predefined scaling factor may be in a range between 1.02 and 1.2, in particular between 1.05 and 1.1, more particularly between 1.06 and 1.08, in case the at least one property of the inductive heating arrangement decreases when an aerosol-generating article is inserted into the device. Likewise, the predefined scaling factor may be in a range between 0.8 and 0.98, in particular between 0.9 and 0.95, more particularly between 0.92 and 0.94, in case the at least one property of the inductive heating arrangement increases when an aerosol-generating article is inserted into the device.

The aforementioned scaling factors have proven to be appropriate in order to clearly distinguish between an article being absent from the cavity or being present in the cavity.

It is also possible that the predetermined threshold value may correspond to a reference value of the at least one property of the inductive heating arrangement-predetermined when an aerosol-generating article comprising a susceptor is either absent from or present in the cavity-plus or minus a predefined offset value, depending on whether the at least one property of the inductive heating arrangement increases or decreases, when an aerosol-generating article is inserted into the device. The offset value may be in a range between 2 percent and 20 percent, in particular between 5 percent and 10 percent, more particularly between 6 percent and 8 percent, of the predetermined reference value of the at least one property of the inductive heating arrangement. The aforementioned offset values also have proven to be appropriate in order to clearly distinguish between an article being absent from the cavity or being present in the cavity.

Preferably, the reference value of the at least one property of the inductive heating arrangement and thus the threshold value may be (initially) predetermined and stored in the control circuitry during the manufacturing of the aerosol-generating device. For this, the device may be calibrated at the manufacturing state either without or with an article being present in the cavity by operating the device such that the control circuitry generates one or more pulses for intermittently powering on the inductive heating arrangement. During the one or more pulses, the control circuit determines a value of the at least one property of the inductive heating arrangement which defines the reference value of the at least one property of the inductive heating arrangement for an article being either absent from or present in the cavity. This reference value is used to determine the threshold value based on the predefined function. The predefined function may be stored in the control circuitry. The thus determined threshold value in turn may be stored in the device in order to be available later during normal user operation for a comparison with a determined value of the at least one property determined during one or more power pulses.

Advantageously, the reference value of the at least one property of the inductive heating arrangement may be updated at predefined regular intervals during the lifetime of the aerosol-generating device. This procedure may help to counteract possible drifts (decrease or increase) of the at least one property which may occur during the lifetime of the aerosol-generating device due to natural altering effects, in particular due to drifts of the electrical parameters of the heating arrangement. For example, in case the electrical conductance of the heating arrangement is used as the at least one property, it has been found that an initial reference value of the conductance being taking at the manufacturing state, for example, when an article was absent from the cavity, may have become smaller when being redetermined after some time. In some case, already after a few heating cycles, the value of the conductance taken when no article is present in the cavity may have become even smaller than the threshold value determined on the basis of the initial reference value having been measured and stored in the device at the manufacturing state. As a result, the control circuitry would always return a value of the conductance being interpreted as indicating that an article is present in the cavity, even in case it is not. Hence, the device would be no longer capable of reliably detecting the insertion or extraction of an article into the cavity.

To counteract a possible malfunction of the article detection, the reference value of the at least one property of the inductive heating arrangement may be updated every tenth time, in particular every fifth time, more particularly every second time, preferably every time after a user experience when an aerosol-generating article comprising a susceptor is absent from the cavity.

Preferably, the reference value of the at least one property of the inductive heating arrangement is updated by redetermining during one or more power pulses the at least one property of the inductive heating arrangement when an aerosol-generating article comprising a susceptor is either absent from or present in the cavity, and by storing the redetermined value in the control circuitry as updated reference value.

The at least one property may be observed by measuring any parameter of the inductive heating arrangement being indicative of the at least one property. The parameter may be measured either directly or indirectly. Preferably, the parameter may be at least one of a current and a voltage. Accordingly, the control circuitry may comprise a measurement device for determining at least one of a current and a voltage indicative of the at least one property of the inductive heating arrangement. In particular, the parameter may be a DC current supplied from a DC power supply of the device to the inductive heating arrangement. Accordingly, the control circuitry may comprise a current measurement device arranged and configured for measuring a DC current supplied from the DC power supply to the inductive heating arrangement. For that purpose, the measurement device may comprise a DC current measurement device arranged in series connection between the DC power supply and the inductive heating arrangement. For example, the measurement device may comprise a resistance and a shunt amplifier. Accordingly, when an aerosol-generating article is inserted into the cavity of the aerosol-generating device, the susceptor becoming present in the cavity increases the equivalent resistance or decreases the conductance, respectively, due to an increase of the resistive load. This in turn causes a decrease of the DC current feeding the inductive heating arrangement. The decrease of the DC current is detected by the current measurement device of the control circuitry which subsequently may activate a heating operation of the inductive heating arrangement for heating the substrate. Likewise, when an aerosol-generating article is extracted from the cavity of the aerosol-generating device, the susceptor becoming absent from the cavity decreases the equivalent resistance or increases the conductance, respectively, due to a decrease of the resistive load. This in turn causes an increase of the DC current feeding the inductive heating arrangement. The increase of the DC current is detected by the current measurement device of the control circuitry which subsequently may enable a next heating operation.

In addition to the current measurement device, the control circuitry may comprise a voltage measurement device arranged and configured for determining a DC voltage supplied to the inductive heating arrangement by the DC power supply. The voltage measurement device may be arranged in parallel connection to a DC power supply of the device for determining a DC voltage supplied to the inductive heating arrangement by the DC power supply.

Furthermore, the control circuitry may be configured to determine a value of an electrical conductance of the inductive heating arrangement from the ratio of the determined DC current to the determined DC voltage. Likewise, the control circuitry may be configured to determine a value of an electrical (equivalent) resistance of the inductive heating arrangement from the ratio of the determined DC voltage to the determined DC current. Advantageously, determining the electrical conductance or the electrical (equivalent) resistance of the inductive heating arrangement from both, the determined DC current and the determined DC voltage, makes account for a drift, in particular gradual decrease of the electrical power used to drive the heating arrangement. Typically, the electrical power used to drive the heating arrangement is provided by a battery. Hence, the control circuitry may properly determine the value of the electrical conductance, irrespective of the actual power provided to the heating arrangement.

As mentioned before, the aerosol-generating device may comprise a power supply, in particular a DC power supply configured to provide a DC supply voltage and a DC supply current to the inductive heating arrangement. Preferably, the power supply is a battery such as a lithium iron phosphate battery. The power supply may be rechargeable. The power supply may have a capacity that allows for the storage of enough energy for one or more user experiences. For example, the power supply may have sufficient capacity to allow for the continuous generation of aerosol for a period of around six minutes or for a period that is a multiple of six minutes. In another example, the power supply may have sufficient capacity to allow for a predetermined number of puffs or discrete activations of the inductive heating arrangement.

In general, the control circuitry may be configured to detect at least one of the insertion of an aerosol-generating article into the cavity in order to start heating operation, the extraction of an aerosol-generating article from the cavity after a heating operation in order to enable heating operation to be restarted, or the extraction of an aerosol-generating article from the cavity during heating operation in order to stop the heating operation.

In the first and the second case, the aerosol-generating device is not in heating operation, but in a specific article detection mode, in particular in an article insertion detection mode or in an article extraction detection mode, respectively. In the third case, the aerosol-generating device is in heating operation, that is, in a heating mode. Nevertheless, in the heating mode, the control circuitry may be able to detect the extraction of an aerosol-generating article from the cavity by determining a value of the at least one property of the inductive heating arrangement and comparing it with a predetermined threshold value, in particular by detecting that the determined value of the at least one property of the inductive heating arrangement determined for one or more power pulses has breached the predetermined threshold value. In the first and the second case, that is, when the device is in the article detection mode, in particular in the article insertion detection mode and in the article extraction detection mode, the power pulses generated by the control circuitry specifically aim at detecting the insertion or the extraction of an aerosol-generating article into or from the cavity. Therefore, the power pulses generated for article detection during the article detection mode, in particular in the article insertion detection mode and in the article extraction detection mode, may be denoted as probe power pulses. Accordingly, the control circuitry may be configured to generate probe power pulses. In the third case, that is, when the device is in a heating mode, the power pulses generated by the control circuitry may aim at heating the aerosol-forming substrate by pulsed heating. Therefore, the power pulses generated during a heating operation, in particular during the heating mode, may be denoted as heating power pulses. In addition, during a heating operation, that is, in the heating mode, the power pulses may also be used to monitor the device for the extraction of an aerosol-generating article from the cavity in order to stop heating operation. That is, the power pulses during the heating mode may also be used for detecting the extraction of an aerosol-generating article from the cavity by determining a value of the at least one property of the inductive heating arrangement and comparing it with a predetermined threshold value, in particular by detecting that the determined value of the at least one property of the inductive heating arrangement determined for one or more power pulses has breached the predetermined threshold value.

In general, the power pulse in the article insertion detection mode and in the article extraction detection mode may be identical. It is also possible that the power pulse in the article insertion detection mode and in the article extraction detection mode may differ from each other by at least one property, such as the amplitude of the power pulse, the pulse duration and the time interval between two consecutive power pulses. Likewise, the power pulse in the article insertion/extraction detection mode and in the heating mode may be identical. It is also possible that the power pulse in the insertion/extraction detection mode and in the heating mode, that is, the probe power pulses and the heating power pulses may differ from each other by at least one property, such as the amplitude of the power pulse, the pulse duration and the time interval between two consecutive power pulses. In particular, the amplitude of the heating power pulses may be larger than the amplitude of the probe power pulses. In addition, the probe power pulses may have a fixed pulse pattern, in particular a fixed periodicity. In contrast, the heating power pulses may have an unfixed, in particular variable pulse pattern, for example in case of a pulse width modulation of the heating power.

The control circuitry may be configured to disable the heating operation of the inductive heating arrangement in response to detecting the extraction of an article from the cavity during a heating operation. Likewise, the control circuitry may be configured to disable the heating operation of the inductive heating arrangement after a previous heating operation, and until after detecting the extraction of an article from the cavity. Advantageously, this prevents a user of the device from starting a new heating operation with a depleted aerosol-generating article. Furthermore, safety may be improved because re-heating a used aerosol-generating article might cause damage to the heating arrangement.

Once the extraction of an article has been detected, disablement of the heating operation should be ceased. Accordingly, the control circuitry may be configured to enable activation of the heating operation of the inductive heating arrangement in response to detecting the extraction of an article from the cavity during a heating operation, and after disabling the heating operation. Likewise, the control circuitry may be configured to enable activation of the heating operation of the inductive heating arrangement after a previous heating operation, and in response to detecting the extraction of an article from the cavity.

In general, heating operation of the inductive heating arrangement may be activated manually, that is, by a user input. Alternatively or in addition, activation of the heating operation may be event-driven, that is, may occur in response to detecting a particular event. Preferably, the control circuitry is configured to start heating operation of the inductive heating arrangement in response to detecting the insertion of the article into the cavity. Advantageously, this enhances the user's convenience as heating operation automatically starts upon insertion of an article into the cavity without the need of any further user input.

The control circuitry may further comprise a motion sensor for detecting movements of the aerosol-generating device. Advantageously, the motion sensor may enable to monitor the device for movements and thus, for example, to detect whether a user is about to extract an aerosol-generating article from the cavity or to insert an article into the cavity and thus to start a new user experience. As an example, the motion sensor may comprise at least one of an accelerometer for measuring accelerations or a gyroscope for measuring an angular orientation or an angular velocity of the device. That is, the motion sensor may be configured to detect at least one of accelerations, an angular orientation and or an angular velocity of the aerosol-generating device, in particular due to a user handling the device. In order to avoid unnecessary pulse generation during idle phases, that is, during periods in which the aerosol-generating device is not used, the control circuitry may be configured to start generating probe power pulses in response, in particular only in response to detecting movements of the aerosol-generating device. Thus, detection of device movements is used to trigger an article detection mode when a user is about to use the device. Advantageously, this allows to save electrical power and thus to increase the overall operation time of the aerosol-generating device. Preferably, the control circuitry is configured to start generating (probe) power pulses, in response to detecting movement of the device reaching or exceeding a pre-determined motion threshold. Likewise, the control circuitry may be configured to stop generating (probe) power pulses after a predetermined time after detecting movement of the device reaching or exceeding a pre-determined motion threshold. The control circuitry may also be configured to stop generating (probe) power pulses in response to detecting movements of the device not reaching the pre-determined motion threshold for a predetermined idle time, or in response to detecting no movements for a predetermined idle time. Advantageously, this procedure also helps to reduce the power consumption and, thus, to increase in the overall operation time of the device.

In order to further reduce the power consumption, the control circuitry may be configured to reduce a number of (probe) power pulses, per time unit, for example, by a factor of two or three, in response to detecting for a predetermined idle time movements of the device not reaching the pre-determined motion threshold or in response to detecting for a predetermined idle time no movements. The idle time may be in a range between 10 seconds and 90 seconds, in particular between 15 seconds and 60 seconds, preferably between 15 seconds and 40 seconds. According to another configuration, the control circuitry may be configured to reduce a number of (probe) power pulses, per time unit, for example, by a factor of two of three, in response to detecting for a predetermined first idle time movements of the device not reaching the pre-determined acceleration threshold or in response to detecting for a predetermined first idle time movements no movements, and subsequently to stop generating power pulses, in particular probe power pulses, in response to detecting for a predetermined second idle time starting after the first idle time movements of the device not reaching the pre-determined acceleration threshold or in response to detecting for a predetermined second idle time starting after the first idle time no movements. Advantageously, this configuration even further reduces the power consumption and, thus, increases the overall operation time of the device even more. The first idle time may be in a range between 5 seconds and 60 seconds, in particular between 10 seconds and 30 seconds, preferably between 15 seconds and 25 seconds. Likewise, the second idle time may be in a range between 10 seconds and 90 seconds, in particular between 15 seconds and 60 seconds, preferably between 15 seconds and 30 seconds.

Alternatively or in addition to triggering the article detection mode by monitoring the device for movements, the article detection mode may also be triggered by other events. For example, the article detection mode may be triggered by extracting the aerosol-generating device from a power charging unit used for re-charging the DC power supply of the device. For that purpose, the control circuit may be configured to detect the extraction of the aerosol-generating device from a power charging unit and to start generating (probe) power pulses in response to detecting the extraction of the aerosol-generating device from the power charging unit. Likewise, the control circuit may be configured to detect the insertion of the aerosol-generating device into a power charging unit and to stop generating (probe) power pulses in response to detecting insertion of the aerosol-generating device into a power charging unit. This procedure avoids unnecessary power consumption and enhances the user's convenience because there is no need for a user to actively start or stop the article detection mode.

The control circuit may be configured to stop of the heating operation of the device subject to various conditions, for example, in response to at least one of detecting a pre-determined number of puffs, detecting that a pre-determined heating time has elapsed, or receiving a user input. Advantageously, any of these conditions may subsequently initiate the detection of the extraction of an aerosol-generating article from the cavity. Accordingly, the control circuit may be configured to start generating power pulses, in particular probe power pulses, for detecting the extraction of the article in response to detecting a stop of the heating operation of the device. As mentioned above, this procedure also enhances the user's convenience.

It is also possible that the control circuitry is configured to stop heating operation of the inductive heating arrangement in response to detecting the extraction of the article from the cavity. Advantageously, this configuration may be used to abort heating operation, for example, if an aerosol-generating article has been extracted untimely, for example, before expiration of the predetermined heating time or before expiration of the predetermined number of puffs or before a user input.

The control circuitry may be configured to verify the insertion of an article into the cavity or the extraction of an article from the cavity by generating at least one verifying power pulse a pre-determined period of time after a first detection of the change of the at least one property of the inductive heating arrangement and by re-detecting the change of at least one property of the inductive heating arrangement.

In order to generate the power pulses for intermittently powering on the inductive heating arrangement, the control circuitry may comprise a switch configured and arranged to control a supply of power from the DC power supply to the inductive heating arrangement. For this, the switch may be intermittently closed and opened such as to intermittently power on the inductive heating arrangement for detecting at least one of the insertion of an aerosol-generating article into the cavity in order to start heating operation (article insertion detection mode), the extraction of an aerosol-generating article from the cavity after a heating operation in order to enable heating operation to be restarted (article extraction detection mode), and the extraction of an aerosol-generating article from the cavity during heating operation in order to stop the heating operation.

The switch may also be used to intermittently power on the inductive heating arrangement during the heating mode of the device in order to generate power pulses for pulsed heating of the aerosol-forming substrate. Accordingly, this mode may be denoted as pulsed heating mode. In that mode, the power pulses may also be used to monitor the device for the extraction of an aerosol-generating article from the cavity in order to stop heating operation. It is also possible that during the heating operation of the aerosol-generating device the switch may be permanently closed to continuously apply a DC voltage from the DC power supply to the inductive heating arrangement. Accordingly, this mode may be denoted as continuous heating mode. In the continuous heating mode, the control circuitry may also be able to detect the extraction of an article from the cavity by determining a value of the at least one property of the inductive heating arrangement and comparing it with a predetermined threshold value, in particular by detecting that the determined value of the at least one property of the inductive heating arrangement has breached the predetermined threshold value.

In general, the pulse duration and the time interval between two consecutive (probe) power pulses should be selected such as to balance the effect of energy depletion and user experience performance. The (probe) power pulses may have a pulse duration in a range between 1 microsecond and 500 microseconds, in particular between 10 microseconds and 300 microseconds, preferably between 15 microseconds and 120 microseconds, most preferably between 30 microseconds to 100 microseconds. As used herein, the term “pulse duration” denotes the time interval during which the heating arrangement is powered on, in particular during which the switch mentioned above is closed. The time interval between two consecutive (probe) power pulses may be in a range between 50 milliseconds and 2 seconds, in particular between 100 milliseconds and 2 seconds, preferably between 500 milliseconds and 1 second. The sum of the pulse duration time and the time interval between two consecutive power pulses may be denoted as the polling time, that is, the difference in time between the start of a pulse and the start of the following one. The polling time may be in a range between 50 milliseconds and 2.5 seconds, in particular between 51 milliseconds and 2.5 milliseconds, more particularly between 100 milliseconds and 2 seconds, preferably between 500 milliseconds and 1 second.

For the article detection the (probe) power pulses are preferably generated for a predetermined period of time only. In case no insertion or extraction of an article has been detected within the predetermined period of time, the generation of the power pulses thus the article detection mode may be stopped in order to safe electrical power, as described above. Likewise, in case the insertion or extraction of an article is detected within the predetermined period of time, the detection mode may be stopped, in particular immediately, in response to detecting the insertion or extraction of the article.

The inductive heating arrangement may be configured to generate a high-frequency alternating magnetic field. As referred to herein, the high-frequency alternating magnetic field may be in the range between 500 kHz (kilo-Hertz) to 30 MHz (Mega-Hertz), in particular between 5 MHz (Mega-Hertz) to 15 MHz (Mega-Hertz), preferably between 5 MHZ (Mega-Hertz) and 10 MHz (Mega-Hertz).

For generating the alternating magnetic field, the inductive heating arrangement may comprise DC/AC converter connected to the DC power supply. The DC/AC converter may include an LC network. For example, the DC/AC converter may comprise a Class-C power amplifier or a Class-D power amplifier or Class-E power amplifier. In particular, the DC/AC converter may comprise a transistor switch and a transistor switch driver circuit and an LC network. The LC network may comprise a series connection of a capacitor and an inductor, and wherein the inductor is configured and arranged to generate the alternating magnetic field within the cavity, in particular for inductively heating the susceptor and for article detection. The LC network may further comprise a shunt capacitor in parallel to the transistor switch. In addition, DC/AC converter may comprise a choke inductor for supplying a DC supply voltage +V_DC from to the DC power supply.

The inductor used to generate the alternating magnetic field within the cavity for inductively heating the susceptor and for article detection may comprise at least one induction coil, in particular a single induction coil or a plurality of induction coils. The number of induction coils may depend on the size and/or number of susceptors. The induction coil or coils may have a shape matching the shape of the one or more susceptors in the aerosol-generating article. Likewise, the induction coil or coils may have a shape to conform to a shape of a housing of the aerosol-generating device. The at least one induction coil may be a helical coil or flat planar coil, in particular a pancake coil or a curved planar coil. The at least one induction coil can be held within one of a housing of the heating arrangement, or a main body or a housing of an aerosol-generating device which comprises the heating arrangement. The at least one induction coil may be wound around a preferably cylindrical coil support, for example a ferrite core. The inductive heating arrangement may be configured to generate the alternating magnetic field continuously following activation of the system or intermittently, such as on a puff by puff basis.

The control circuit may be configured to control the overall operation of the aerosol-generating device. The control circuitry and at least parts of the inductive heating arrangement may be integral part of an overall electrical circuitry of the aerosol-generating device.

The control circuitry may comprise a microprocessor, for example a programmable microprocessor, a microcontroller, or an application specific integrated chip (ASIC) or other electronic circuitry capable of providing control. The control circuitry may comprise at least one of a transimpedance amplifier for current-to-voltage conversion, an inverting signal amplifier, a single-ended to-differential converter, an analog-digital converter and a micro-controller. The microprocessor may be configured to at least one of: to control the switch used to generate power pulses for intermittently powering on the inductive heating arrangement, to read out the measurement device for measuring the current supplied from the DC power supply to the inductive heating arrangement, and to control the transistor switch driver circuit of the inductive heating arrangement. The control circuitry may be or may be art of an overall controller of the aerosol-generating device. The control circuitry and at least a portion of the inductive heating arrangement (apart from the inductor) may be arranged at a common printed circuit board. This proves particularly advantageous with regard to a compact design of the heating arrangement.

The receiving cavity may comprise an insertion opening through which an aerosol-generating article may be inserted into the receiving cavity. As used herein, the direction in which the aerosol-generating article is inserted is denoted as insertion direction. Preferably, the insertion direction corresponds to the extension of a length axis, in particular a center axis of the receiving cavity. Upon insertion into the receiving cavity, at least a portion of the aerosol-generating article may still extend outwards through the insertion opening. The outwardly extending portion preferably is provided for interaction with a user, in particular for being taken into a user's mouth. Hence, during use of the device, the insertion opening may be close to the mouth. Accordingly, as used herein, sections close to the insertion opening or close to a user's mouth in use of the device, respectively, are denoted with the prefix “proximal”. Sections which are arranged further away are denoted with the prefix “distal”. With regard to this convention, the receiving cavity may be arranged or located in a proximal portion of the aerosol-generating device. The insertion opening may be arranged or located at a proximal end of the aerosol-generating device, in particular at a proximal end of the receiving cavity. In general, the receiving cavity may have any suitable shape. In particular, the shape of the receiving cavity may correspond to the shape of the aerosol-generating article to be received therein. Preferably, the receiving cavity may have a substantially cylindrical shape or a tapered shape, for example, a substantially conical or a substantially frustoconical shape.

The aerosol-generating device may further comprise optical or haptic indication means for indicating the detection of at least one of the extraction of an article from the cavity, the insertion of the article into the cavity, disablement or enablement of heating operation of the inductive heating arrangement. Advantageously, such indication means may enhance the ease of use and the user's convenience.

The present invention further relates to an aerosol-generating system comprising an aerosol-generating device according to the invention and as described herein. The system further comprises an aerosol-generating article, wherein at least a portion of the article may be removably receivable or removably received in the receiving cavity of the device. The article comprises at least one aerosol-forming substrate and an inductively heatable susceptor for heating the substrate when the article is received in the cavity.

The aerosol-generating article may be a consumable, in particular intended for single use. The aerosol-generating article may be a tobacco article. In particular, the article may be a rod-shaped article, preferably a cylindrical rod-shaped article, which may resemble conventional cigarettes. Preferably, the article may be an elongate article or a rod-shaped article. The elongate or rod-shaped article may have a shape resembling the shape of conventional cigarettes. The aerosol-generating article, in particular elongate or rod-shaped article, may have a circular or elliptical or oval or square or rectangular or triangular or a polygonal cross-section.

As an example, the aerosol-generating article may be a rod-shaped article, in particular a cylindrical article, comprising one or more of the following elements: a distal front plug element, a substrate element, a first tube element, a second tube element, and a filter element. The substrate element preferably comprises the at least one aerosol-forming substrate to be heated and the susceptor arrangement in thermal contact with or thermal proximity to the aerosol-forming substrate. The substrate element may have a length of 10 millimeter to 14 millimeter, for example, 12 millimeter. The first tube element is more distal than the second tube element. Preferably, the first tube element is proximal of the substrate element, whereas the second tube element is proximal of the first tube element and distal of the filter element, that is, between the first tube element and the filter element. At least one of the first tube element and the second tube element may comprise a central air passage. A cross-section of the central air passage of the second tube element may be larger than a cross-section of the central air passage of the first tube element. Preferably, at least one of the first tube element and the second tube element may comprise a hollow cellulose acetate tube. At least one of the first tube element and the second tube element may have a length of 6 millimeter to 10 millimeter, for example, 8 millimeters. The filter element preferably serves as a mouthpiece, or as part of a mouthpiece together with the second tube element. As used herein, the term “mouthpiece” refers to a portion of the article through which the aerosol exits the aerosol-generating article. The filter element may have a length of 10 millimeter to 14 millimeter, for example, 12 millimeter. The distal front plug element may be used to cover and protect the distal front end of the substrate element. The distal front plug element may have a length of 3 millimeter to 6 millimeter, for example, 5 millimeter. The distal front plug element may be made of the same material as the filter element. All of the aforementioned elements may be sequentially arranged along a length axis of the article in the above described order, wherein the distal front plug element preferably is arranged at a distal end of the article and the filter element preferably is arranged at a proximal end of the article. Each of the aforementioned elements may be substantially cylindrical. In particular, all elements may have the same outer cross-sectional shape and/or dimensions. In addition, the elements may be circumscribed by one or more outer wrappers such as to keep the elements together and to maintain the desired cross-sectional shape of the rod-shaped article. Preferably, the wrapper is made of paper. The wrapper may further comprise adhesive that adheres the overlapped free ends of the wrapper to each other. For example, the distal front plug element, the substrate element and the first tube element may be circumscribed by a first wrapper, and the second tube element and the filter element may be circumscribed by a second wrapper. The second wrapper may also circumscribe at least a portion of the first tube element (after being wrapped by the first wrapper) to connect the distal front plug element, the substrate element and the first tube element being circumscribed by a first wrapper to the second tube element and the filter element. The second wrapper may comprise perforations around its circumference.

As used herein, the term “aerosol-forming substrate” relates to a substrate capable of releasing volatile compounds that can form an aerosol when heated. The aerosol-forming substrate may be a solid aerosol-forming substrate or a liquid aerosol-forming substrate or gel-like aerosol-forming substrate. The aerosol-forming substrate may comprise a tobacco-containing material containing volatile tobacco flavor compounds, which are released from the substrate upon heating. Alternatively or additionally, the aerosol-forming substrate may comprise a non-tobacco material. The aerosol-forming substrate may further comprise an aerosol former. Examples of suitable aerosol formers are glycerin and propylene glycol. The aerosol-forming substrate may also comprise other additives and ingredients, such as nicotine or flavoring substances. In particular, liquid aerosol-forming substrate may include water, solvents, ethanol, plant extracts and natural or artificial flavors. The aerosol-forming substrate may also be a paste-like material, a sachet of porous material comprising aerosol-forming substrate, or, for example, loose tobacco mixed with a gelling agent or sticky agent, which could include a common aerosol former such as glycerin, and then is compressed or molded into a plug.

As used herein, the term “susceptor” refers to an element comprising a material that is capable of being inductively heated within an alternating electromagnetic field. This may be the result of at least one of hysteresis losses or eddy currents induced in the susceptor, depending on the electrical and magnetic properties of the susceptor material.

The susceptor may comprise a variety of geometrical configurations. The susceptor may be one of a particulate susceptor, or a susceptor filament, or a susceptor mesh, or a susceptor wick, or a susceptor pin, or a susceptor rod, or a susceptor blade, or a susceptor strip, or a susceptor sleeve, or a susceptor cup or a cylindrical susceptor, or a planar susceptor. For example, the susceptor may be an elongated susceptor strip having a length in a range of 8 mm (millimeter) to 16 mm (millimeter), in particular, 10 mm (millimeter) to 14 mm (millimeter), preferably 12 mm (millimeter). A width of the susceptor strip may be, for example, in a range of 2 mm (millimeter) to 6 mm (millimeter), in particular, 4 mm (millimeter) to 5 mm (millimeter). A thickness of the susceptor strip preferably is in a range of 0.03 mm (millimeter) to 0.15 mm (millimeter), more preferably 0.05 mm (millimeter) to 0.09 mm (millimeter).

The susceptor may be a multi-layer susceptor, for example a multi-layer susceptor strip. In particular, the multi-layer susceptor may comprise a first susceptor material and a second susceptor material. The first susceptor material preferably is optimized with regard to heat loss and thus heating efficiency. For example, the first susceptor material may be aluminum, or a ferrous material such as a stainless steel. In contrast, the second susceptor material preferably is used as temperature marker. For this, the second susceptor material is chosen such as to have a Curie temperature corresponding to a predefined heating temperature of the susceptor assembly. At its Curie temperature, the magnetic properties of the second susceptor change from ferromagnetic to paramagnetic, accompanied by a temporary change of its electrical resistance. Thus, by monitoring a corresponding change of the electrical current absorbed by the induction source it can be detected when the second susceptor material has reached its Curie temperature and, thus, when the predefined heating temperature has been reached. The second susceptor material preferably has a Curie temperature that is below the ignition point of the aerosol-forming substrate, that is, preferably lower than 500 degrees Celsius. Suitable materials for the second susceptor material may include nickel and certain nickel alloys.

Further features and advantages of the aerosol-generating system and the aerosol-generating article according to the present invention have already been described above with regard to the aerosol-generating device according to the present invention and equally apply.

The present invention further relates to an aerosol-generating article of an aerosol-generating system according to present invention or for use with an aerosol-generating device according to present invention. The aerosol-generating article comprises an aerosol-forming substrate and an inductively heatable susceptor for heating the substrate. Further features and advantages of the aerosol-generating article have already been described above with regard to the aerosol-generating device and the aerosol-generating system according to the present invention and equally apply.

The present invention further relates to a method for detecting whether an aerosol-generating article having an inductively heatable susceptor is present in or absent from a cavity of an aerosol-generating device, wherein the device comprises a cavity for removably receiving at least a portion of the article, an inductive heating arrangement configured to generate an alternating magnetic field within the cavity for inductively heating the susceptor of the article when the article is received in the cavity. Preferably, the aerosol-generating device is an aerosol-generating device according to the present invention and as describes herein. The method comprises:
determining during one or more power pulses of the inductive heating arrangement a value of at least one property of the inductive heating arrangement, the value depending on an article with a susceptor being present in or absent from the cavity, and
   detecting at least one of the insertion of an article into the cavity or the extraction of an article from the cavity based on the determined value and a predetermined threshold value, in particular based on a comparison of the determined value with a predetermined threshold value, more particularly in response to the determined value having breached a predetermined threshold value.

As described above with respect to the device, the predetermined threshold value is a predefined function of a reference value of the at least one property of the inductive heating arrangement predetermined when an aerosol-generating article comprising a susceptor is absent from or present in the cavity. In particular, the predetermined threshold value may correspond to a reference value of the at least one property of the inductive heating arrangement-predetermined when an aerosol-generating article comprising a susceptor is absent from or present in the cavity-times a predefined scaling factor. The predefined scaling factor is in a range between 0.8 and 0.98, in particular between 0.9 and 0.95, more particularly between 0.92 and 0.94, or wherein the predefined scaling factor is in a range between 1.02 and 1.2, in particular between 1.05 and 1.1, more particularly between 1.06 and 1.08. Likewise, the predetermined threshold value may correspond to a reference value of the at least one property of the inductive heating arrangement-predetermined when an aerosol-generating article comprising a susceptor is absent from or present in the cavity-plus or minus a predefined offset value. The offset value may be in a range between 2 percent and 20 percent, in particular between 5 percent and 10 percent, more particularly between 6 percent and 8 percent, of the predetermined reference value of the at least one property of the inductive heating arrangement.

Preferably, the reference value of the at least one property of the inductive heating arrangement may be initially predetermined and stored in the aerosol-generating device during the manufacturing of the device.

As also described above with respect to the device, the reference value and the threshold value may be subject to drifts of the electrical parameters of the heating arrangement. Accordingly, the method may further comprise updating the reference value of the at least one property of the inductive heating arrangement at predefined regular intervals during the lifetime of the aerosol-generating device. In particular, updating the reference value of the at least one property of the inductive heating arrangement may occur every tenth time, in particular every fifth time, more particularly every second time, preferably every time after a user experience when an aerosol-generating article comprising a susceptor is absent from the cavity. Updating the reference value of the at least one property of the inductive heating arrangement may comprise redetermining during one or more power pulses the at least one property of the inductive heating arrangement when an aerosol-generating article comprising a susceptor is absent or present in from the cavity, and storing the redetermined value in the device as updated reference value.

Further features and advantages of the method according to the present invention have already been described above with regard to aerosol-generating device and the aerosol-generating system according to the present invention and equally apply.

The invention is defined in the claims. However, below there is provided a non-exhaustive list of non-limiting examples. Any one or more of the features of these examples may be combined with any one or more features of another example, embodiment, or aspect described herein.

Example Ex1: An aerosol-generating device for heating an aerosol-forming substrate that is capable to form an inhalable aerosol when heated, the device comprising:
a cavity for removably receiving at least a portion of an aerosol-generating article, the article including the aerosol-forming substrate and an inductively heatable susceptor for heating the substrate;
an inductive heating arrangement configured to generate an alternating magnetic field within the cavity for inductively heating the susceptor of the article when the article is received in the cavity;
a control circuitry configured to generate power pulses for intermittently powering on the inductive heating arrangement, to determine during one or more power pulses a value of at least one property of the inductive heating arrangement which has different values depending on an article with a susceptor being present in or absent from the cavity, and to detect at least one of the insertion of an article into the cavity or the extraction of an article from the cavity based on the determined value and a predetermined threshold value, in particular based on a comparison of the determined value with a predetermined threshold value.

Example EX1a: An aerosol-generating device for heating an aerosol-forming substrate that is capable to form an inhalable aerosol when heated, the device comprising:
a cavity for removably receiving at least a portion of an aerosol-generating article, the article including the aerosol-forming substrate and an inductively heatable susceptor for heating the substrate;
an inductive heating arrangement configured to generate an alternating magnetic field within the cavity for inductively heating the susceptor of the article when the article is received in the cavity;
a control circuitry configured to generate power pulses for intermittently powering on the inductive heating arrangement, to determine during one or more power pulses a value of at least one property of the inductive heating arrangement which has different values depending on an article with a susceptor being present in or absent from the cavity, and to detect at least one of the insertion of an article into the cavity or the extraction of an article from the cavity in response to the determined value having breached a predetermined threshold value.

Example Ex2: The aerosol-generating device according to example Ex1 or example Ex1a, wherein the predetermined threshold value is a predefined function of a reference value of the at least one property of the inductive heating arrangement predetermined when an aerosol-generating article comprising a susceptor is absent from or present in the cavity.

Example Ex3: The aerosol-generating device according to any one of the preceding examples, wherein the predetermined threshold value corresponds to a reference value of the at least one property of the inductive heating arrangement-predetermined when an aerosol-generating article comprising a susceptor is absent from or present in the cavity-times a predefined scaling factor.

Example Ex4: The aerosol-generating device according to example Ex3, wherein the predefined scaling factor is in a range between 0.8 and 0.98, in particular between 0.9 and 0.95, more particularly between 0.92 and 0.94, or wherein the predefined scaling factor is in a range between 1.02 and 1.2, in particular between 1.05 and 1.1, more particularly between 1.06 and 1.08.

Example Ex5: The aerosol-generating device according to any one of example Ex1, example Ex1a, or example Ex2, wherein the predetermined threshold value corresponds to a reference value of the at least one property of the inductive heating arrangement—predetermined when an aerosol-generating article comprising a susceptor is absent from or present in the cavity—plus or minus a predefined offset value.

Example Ex6: The aerosol-generating device according to example Ex5, wherein the offset value is in a range between 2 percent and 20 percent, in particular between 5 percent and 10 percent, more particularly between 6 percent and 8 percent, of the predetermined reference value of the at least one property of the inductive heating arrangement.

Example Ex7: The aerosol-generating device according to any one of the preceding examples, wherein the reference value of the at least one property of the inductive heating arrangement is predetermined and stored in the control circuitry during the manufacturing of the aerosol-generating device.

Example Ex8: The aerosol-generating device according to any one of the preceding examples, wherein the reference value of the at least one property of the inductive heating arrangement is updated at predefined regular intervals during the lifetime of the aerosol-generating device

Example Ex9: The aerosol-generating device according to example Ex8, wherein the reference value of the at least one property of the inductive heating arrangement is updated every tenth time, in particular every fifth time, more particularly every second time, preferably every time after a user experience when an aerosol-generating article comprising a susceptor is absent from the cavity.

Example Ex10: The aerosol-generating device according to any one of example Ex8 or example Ex9, wherein the reference value of the at least one property of the inductive heating arrangement is updated by redetermining during one or more power pulses the at least one property of the inductive heating arrangement when an aerosol-generating article comprising a susceptor is absent from or present in the cavity, and by storing the redetermined value in the control circuitry as updated reference value.

Example Ex11: The aerosol-generating device according to any one of the preceding examples, wherein the at least one property of the inductive heating arrangement is one of a current, a voltage, an electrical resistance, an electrical conductance, a frequency, a phase shift, a flux, and an inductance of the inductive heating arrangement.

Example Ex12: The aerosol-generating device according to any one of the preceding examples, wherein the control circuitry comprises a measurement device for determining at least one of a current and a voltage indicative of the at least one property of the inductive heating arrangement.

Example Ex13: The aerosol-generating device according to any one of the preceding examples, wherein the control circuitry comprises a current measurement device for determining a DC current drawn by the inductive heating arrangement from a DC power supply of the device, and a voltage measurement device for determining a DC voltage supplied to the inductive heating arrangement by the DC power supply, and wherein the control circuitry is configured to determine a value of an electrical conductance of the inductive heating arrangement from the ratio of the determined DC current to the determined DC voltage.

Example Ex14: An aerosol-generating system comprising an aerosol-generating device according to any one of the preceding examples and an aerosol-generating article for use with the device, wherein at least a portion of the article is removably receivable or removably received in the receiving cavity of the device, and wherein the article comprises an aerosol-forming substrate and an inductively heatable susceptor for heating the substrate, when the article is received in the cavity.

Example Ex15: A method for detecting whether an aerosol-generating article having an inductively heatable susceptor is present in or absent from a cavity of an aerosol-generating device, wherein the device comprises a cavity for removably receiving at least a portion of the article, an inductive heating arrangement configured to generate an alternating magnetic field within the cavity for inductively heating the susceptor of the article when the article is received in the cavity, the method comprising:
determining during one or more power pulses of the inductive heating arrangement a value of at least one property of the inductive heating arrangement, the value depending on an article with a susceptor being present in or absent from the cavity, and
detecting at least one of the insertion of an article into the cavity or the extraction of an article from the cavity based on the determined value and a predetermined threshold value, in particular based on a comparison of the determined value with a predetermined threshold value.

Example 15a: A method for detecting whether an aerosol-generating article having an inductively heatable susceptor is present in or absent from a cavity of an aerosol-generating device, wherein the device comprises a cavity for removably receiving at least a portion of the article, an inductive heating arrangement configured to generate an alternating magnetic field within the cavity for inductively heating the susceptor of the article when the article is received in the cavity, the method comprising:
determining during one or more power pulses of the inductive heating arrangement a value of at least one property of the inductive heating arrangement, the value depending on an article with a susceptor being present in or absent from the cavity, and
detecting at least one of the insertion of an article into the cavity or the extraction of an article from the cavity in response to the determined value having breached a predetermined threshold value.

Example Ex16: The method according to example Ex 15 or example 15a, wherein the predetermined threshold value is a predefined function of a reference value of the at least one property of the inductive heating arrangement predetermined when an aerosol-generating article comprising a susceptor is absent from or present in the cavity.

Example Ex16a: The method according to example Ex 16, further comprising updating the reference value of the at least one property of the inductive heating arrangement at predefined regular intervals during the lifetime of the aerosol-generating device.

Example Ex17: The method according to example Ex 16a, wherein updating the reference value of the at least one property of the inductive heating arrangement occurs every tenth time, in particular every fifth time, more particularly every second time, preferably every time after a user experience when an aerosol-generating article comprising a susceptor is absent from the cavity.

Example Ex18: The method according to example Ex 16a or example Ex17, wherein updating the reference value of the at least one property of the inductive heating arrangement comprises redetermining during one or more power pulses the at least one property of the inductive heating arrangement when an aerosol-generating article comprising a susceptor is absent from or present in the cavity, and storing the redetermined value in the device as updated reference value.

Example Ex19: The method according to any of examples Ex 15 to Ex18, wherein the predetermined threshold value corresponds to a reference value of the at least one property of the inductive heating arrangement-predetermined when an aerosol-generating article comprising a susceptor is absent from or present in the cavity—times a predefined scaling factor.

Example Ex20: The method according to example Ex19, wherein the predefined scaling factor is in a range between 0.8 and 0.98, in particular between 0.9 and 0.95, more particularly between 0.92 and 0.94, or wherein the predefined scaling factor is in a range between 1.02 and 1.2, in particular between 1.05 and 1.1, more particularly between 1.06 and 1.08.

Example Ex21: The method according to any of examples Ex 15 to Ex18, wherein the predetermined threshold value corresponds to a reference value of the at least one property of the inductive heating arrangement-predetermined when an aerosol-generating article comprising a susceptor is absent from or present in the cavity-plus or minus a predefined offset value.

Example Ex22: The method according to example Ex21, wherein the offset value is in a range between 2 percent and 20 percent, in particular between 5 percent and 10 percent, more particularly between 6 percent and 8 percent, of the predetermined reference value of the at least one property of the inductive heating arrangement.

Examples will now be further described with reference to the figures in which:

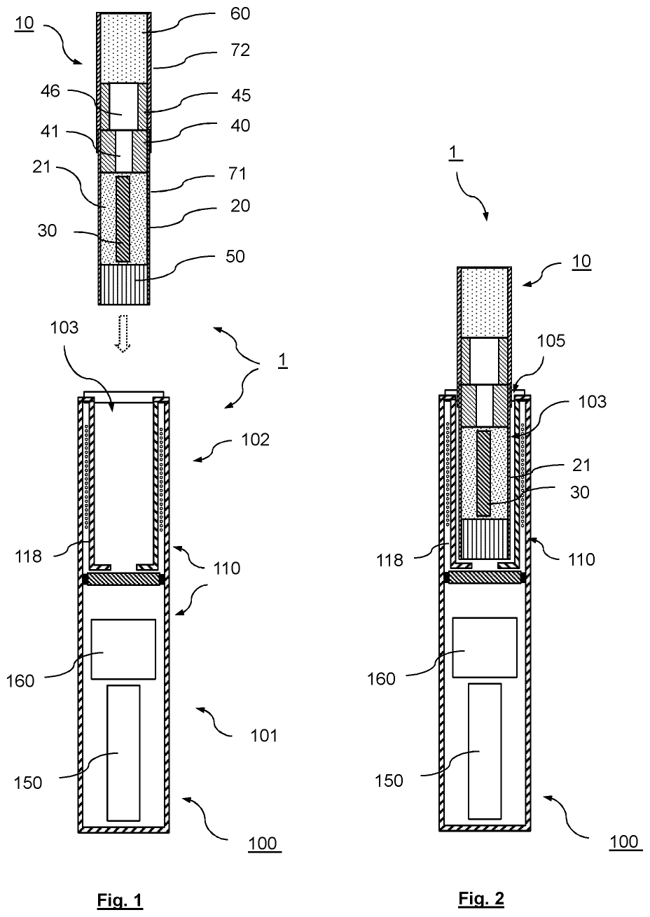

FIGS. 1-2 schematically illustrate an exemplary embodiment of an aerosol-generating system according to the present invention, including an aerosol-generating device and an aerosol-generating article for use with the device;

FIG. 3 schematically illustrates the inductive heating arrangement of the aerosol-generating device according to FIGS. 1 and 2;

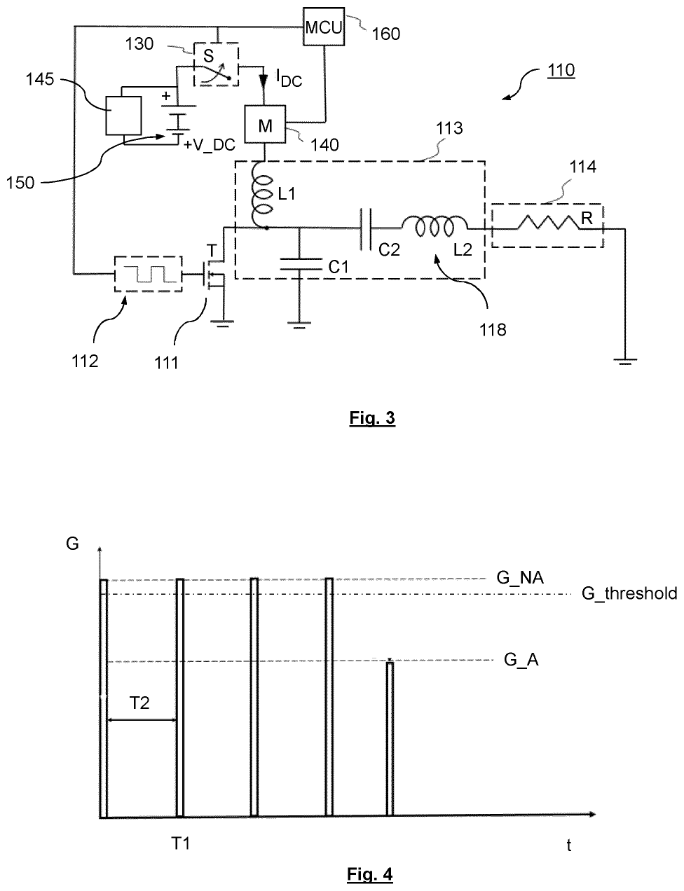

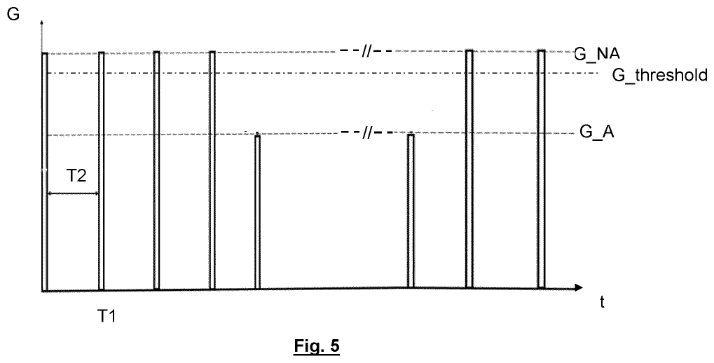

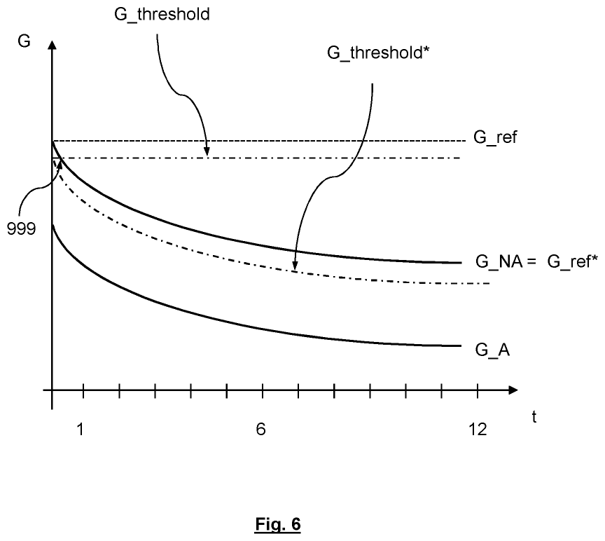

FIGS. 4-5 schematically illustrate operational details of the method according to the present invention; and

FIG. 6 schematically illustrates the drift of the conductance of the heating arrangement shown in FIG. 1 and FIG. 2 during its lifetime.

FIG. 1 and FIG. 2 schematically illustrate an exemplary embodiment of an aerosol-generating system 1 according to the present invention which is used for generating an inhalable aerosol by heating an aerosol-forming substrate. The system 1 comprises an aerosol-generating article 10 which includes the aerosol-forming substrate 21 to be heated, and an aerosol-generating device 100 for heating the substrate upon engaging the article 10 with the device 100. As can be particularly seen in FIG. 1, the aerosol-generating article 10 has a substantially rod-like shape resembling the shape of a conventional cigarette. In the present embodiment, the article 10 comprises five elements sequentially arranged in coaxial alignment: a distal front plug element 50, a substrate element 20, a first tube element 40, a second tube element 45, and a filter element 60. The distal front plug element 50 is arranged at a distal end of the article 10 to cover and protect the distal front end of the substrate element 20, whereas the filter element 60 is arranged at a proximal end of the article 10. Both, the distal front plug element 50 and the filter element 60 may be made of the same filter material. The filter element 60 preferably serves as a mouthpiece, preferably as part of a mouthpiece together with the second tube element 45. The filter element may have a length of 10 millimeter to 14 millimeter, for example, 12 millimeter, whereas the distal front plug element 50 may have a length of 3 millimeter to 6 millimeter, for example, 5 millimeter. The substrate element 20 comprises an aerosol-forming substrate 21 to be heated as well as a susceptor 30 that is configured and arranged to heat the substrate 21 when being exposed to an alternating magnetic field. The susceptor arrangement 30 is fully embedded in the substrate 21 such as to be in direct thermal contact with the substrate 21. The substrate element 20 may have a length of 10 millimeter to 14 millimeter, for example, 12 millimeter. Each one of the first and the second tube element 40, 45 is a hollow cellulose acetate tube having a central air passage 41, 46, wherein a cross-section of the central air passage 46 of the second tube element 45 is larger than a cross-section of the central air passage 41 of the first tube element 40. The first and second tube elements 40, 14 may have a length of 6 millimeter to 10 millimeter, for example, 8 millimeters. In use, an aerosol formed by volatile compounds released from the substrate element 20 is drawn through the first and second tube element 40, 45 and the filter element 60 towards the proximal end of the article 10. Each of the aforementioned elements 50, 20, 40, 45, 60 may be substantially cylindrical. In particular, all elements 50, 20, 40, 45, 60 may have the same outer cross-sectional shape and dimensions. In addition, the elements may be circumscribed by one or more outer wrappers such as to keep the elements together and to maintain the desired cross-sectional shape of the rod-shaped article. In the present embodiment, the distal front plug element 50, the substrate element 20 and the first tube element 40 are circumscribed by a first wrapper 71, whereas the second tube element 45 and the filter element 60 are circumscribed by a second wrapper 72. The second wrapper 72 also circumscribes at least a portion of the first tube element 40 (after being wrapped by the first wrapper 71) to connect the distal front plug element 50, the substrate element 20 and the first tube element 40 (being circumscribed by the first wrapper 71) to the second tube element 45 and the filter element 60. Preferably, the first and the second wrapper 71, 72 are made of paper. In addition, the second wrapper 72 may comprise perforations around its circumference (not shown). The wrappers 71, 72 may further comprise adhesive that adheres the overlapped free ends of the wrappers to each other.

The elongate aerosol-generating device 100 basically has two portions: a proximal portion 102 and a distal portion 101. In the proximal portion 102, the device 100 comprises a cavity 103 for removably receiving at least a portion of the aerosol-generating article 10. In the distal portion 101, the device 100 comprises a power supply 150 and a controller 160 for powering and controlling operation of the device 100. For heating substrate, the device 100 comprises an inductive heating arrangement 110 including an induction coil 118 for generating an alternating, in particular high-frequency magnetic field within the cavity 103. In the present embodiment, the induction coil 118 is a helical coil which is arranged in the proximal portion 102 of the device such as to circumferentially surround the cylindrical receiving cavity 103. The coil 118 is arranged such that the susceptor 30 of the aerosol-generating article 10 experiences the electromagnetic field upon engaging the article 10 with the device 100. The alternating magnetic field is used to inductively heat the susceptor 30 within the aerosol-generating article 10 when the article 10 is received in the cavity 103. Thus, upon inserting the article 10 into the cavity 103 of the device 100 (see FIG. 2) and activation of the heating arrangement 110, the alternating electromagnetic field within the cavity 103 induces eddy currents and/or hysteresis losses in the susceptor 30, depending on the magnetic and electric properties of the susceptor material. As a consequence, the susceptor 30 heats up until reaching a temperature sufficient to vaporize the aerosol-forming substrate 21 surrounding the susceptor 30 within the article 10. In use of the system, when a user takes a puff, that is, when a negative pressure is applied at the filter element 60 of the article 10, air is drawn into the cavity 103 at the rim of the article insertion opening 105 of the device 100. The air flow further extends towards the distal end of the cavity 103 through a passage which is formed between the inner surface of the cylindrical cavity 103 and the outer surface of the article 10. At the distal end of the cavity 103, the air flow enters the aerosol-generating article 10 through the substrate element 20 and further passes through the first and second tube elements 40, 45 and the filter element 60 where it finally exits the article 10. In the substrate element 20, vaporized material from the aerosol-forming substrate 21 is entrained into the air flow. Subsequently, when passing through the first and second tube elements 40, 45 and the filter element 60 the air flow including the vaporized material cools down such as to form an aerosol escaping the article 10 through the filter element 60.

FIG. 3 shows further details of the inductive heating arrangement 110 used to generate an alternating magnetic field within the cavity 103. According to the present embodiment, the inductive heating arrangement 110 comprises a DC/AC inverter which is connect to the DC power supply 150 shown in FIGS. 1 and 2. The DC/AC inverter includes a Class-E power amplifier which in turn includes the following components: a transistor switch 111 comprising a Field Effect Transistor T (FET), for example a Metal-Oxide-Semiconductor Field Effect Transistor (MOSFET), a transistor switch supply circuit indicated by the arrow 112 for supplying the switching signal (gate-source voltage) to the transistor switch 111, and an LC load network 113 comprising a shunt capacitor C1 and a series connection of a capacitor C2 and inductor L2. The inductor L2 corresponds to the induction coil 118 shown in FIGS. 1 and 2 used to generate an alternating magnetic field within the cavity 103. In addition, there is provided a choke L1 for supplying a DC supply voltage +V_DC from to the DC power supply 150. Also shown in FIG. 3 is the ohmic resistance R representing the total equivalent resistance or total resistive load 114, which—in use of the system, that is, when the article is inserted in the cavity 103 of the device 100—is the sum of the ohmic resistance of the inductor coil 118, marked as L2, and the ohmic resistance of the susceptor. Otherwise, in case no article is inserted in the cavity 103, the equivalent resistance or resistive load 114 only corresponds to the ohmic resistance of the inductor coil 118.

For various purposes, in particular for automatically enabling or disabling the heating process and/or for preventing a user from re-heating of a depleted aerosol-generating article, it is desirable to detect at least one of the insertion of an aerosol-generating article into the receiving cavity 103 and the extraction of an aerosol-generating article from the receiving cavity 103. For this, the aerosol-generating device according to the present embodiment may be operated in at least one of an article insertion detection mode or an article extraction detection mode.

According to the present invention, detecting the insertion and/or extraction of the article 10 into or from the cavity 103 is realized via the heating arrangement 110. Advantageously, this avoids additional assembly space for separate sensor means. The basic idea is to determine a value of at least one property of the inductive heating arrangement 110, the value depending on an article 10 with a susceptor 30 being present in or absent from the cavity 103, and to detect at least one of the insertion of an article 10 into the cavity 103 or the extraction of an article 10 from the cavity 103 based on the determined value and a predetermined threshold value, in particular in response to the determined value having breached a predetermined threshold value. In the present embodiment, it is the electrical conductance of the heating arrangement 110 which is used as the property of the inductive heating arrangement being indicative of the presence or absence of an article 10 in the receiving cavity 103. As explained above, the value of the electrical conductance of the heating arrangement 110 is the inverse of the total equivalent resistance or total resistive load 114 of the heating arrangement 110 which both depend on the presence or absence of the susceptor 30 in the vicinity of the induction coil 118. When the article is inserted in the cavity 103 of the device 100, the total equivalent resistance corresponds to the sum of the ohmic resistance of the inductor coil 118 and the ohmic resistance of the susceptor 30. In contrast, when no article is received in the cavity 103, the total equivalent resistance corresponds to the ohmic resistance of the inductor coil 118 only. This change of the equivalent resistance is accompanied by a corresponding inverse change of the electrical conductance of the heating arrangement 110. That is, when an aerosol-generating article 10 is inserted into the cavity 103 of the aerosol-generating device 100, the presence of the susceptor 30 causes a decrease of the conductance of the heating arrangement 110 due to the increase of the resistive load 114. Vice versa, when an aerosol-generating article 10 is extracted from the cavity 103, the absence of the susceptor 30 causes an increase of the conductance of the heating arrangement 110 due to the decrease of the resistive load 114.

The electrical conductance of the heating arrangement 110 can be detected via the DC voltage V_DC and the DC current I_DC provided from the DC power supply 150 to the inductive heating arrangement 110, that is, to the LC load network 113. For this, the aerosol-generating device 100 comprises a current measurement device 140 in series connection between the DC power supply 150 and the LC load network 113, as well as a voltage measurement device 145 in parallel connection to the DC power supply 150. The current measurement device 140 and the voltage measurement device 145 are both part of a control circuitry which may be or may be part of an overall controller of the aerosol-generating device 100. The control circuitry is configured to determine a value of an electrical conductance of the inductive heating arrangement 110 from the ratio of the determined DC current to the determined DC voltage.

In order to reduce the overall power consumption when the aerosol-generating device 100 is in an article detection mode (e.g. either in an article insertion detection mode or an article extraction detection mode), the heating assembly 110 is not operated in a continuous mode, but in a pulsed mode. For this, the aerosol-generating device 100 comprises a switch 130 that is arranged and configured to control a supply of power from the DC power supply 150 to the inductive heating arrangement 110. In the present embodiment, the switch 130 is arranged in series connection between the DC power supply 150 and the LC load network 113. During the article detection mode, the switch is intermittently opened and closed such as to generate power pulses for intermittently powering on the inductive heating arrangement 130. In contrast, during the heating mode of the aerosol-generating device 100 the switch 130 may be permanently closed to continuously apply a DC voltage from the DC power supply to the inductive heating arrangement 110. It is also possible that the switch may be intermittently closed and opened during the heating mode of the aerosol-generating device such as to generate heating power pulses for pulsed heating of the aerosol-forming substrate. Accordingly, this mode may be denoted as pulsed heating mode.

As shown in FIG. 3, a microprocessor 160 of the control circuitry is used to control the switch 130 in order to generate power pulses for intermittently powering on the inductive heating arrangement 110. The microprocessor 160 is also configured to control the transistor switch driver circuit 112 of the inductive heating arrangement 110, and to read out the current measurement device 140 and the voltage measurement device 145 in order to determine the value of an electrical conductance of the inductive heating arrangement 110 from the ratio of the determined DC current to the determined DC voltage. In the article insertion/extraction detection mode, the microprocessor 160 starts driving the switch 130 by closing it for a pre-determined closing time interval, thereby generating a power pulse having a pulse duration T1 corresponding to the closing time interval. The pulse duration T1 may be in a range between 1 microsecond and 500 microseconds, in particular between 10 microseconds and 300 microseconds, preferably between 15 microseconds and 120 microseconds, most preferably between 30 microseconds to 100 microseconds. At the end of the closing time interval, the microprocessor 160 opens the switch 130 again for a pre-determined opening time interval, thereby interrupting the current passage to the heating arrangement. The opening time interval corresponds to the time interval between two consecutive power pulses, which for the article detection may be in a range between 50 milliseconds and 2 seconds, in particular between 100 milliseconds and 2 seconds, preferably between 500 milliseconds and 1 second. Closing and opening of the switch 130 may occur at regular time intervals such as to generate periodic power pulses for periodically powering on the inductive heating arrangement 110. Thus, the sum of the closing time interval and the opening time interval, or the sum of the pulse duration and the time interval between two consecutive power pulses corresponds to the periodicity of the pulse series. In general, the time interval between two consecutive probe power pulses T2 should be selected such as to balance the effect of energy depletion and user experience performance. The pulse duration T1 should be kept as minimal as possible but such to provide a reliable measurement of the conductance.

FIG. 4 is a graph showing the evolution of the conductance G determined for a series of power pulses over time t. In the present embodiment, a series of power pulses is generated with a pulse duration T1 of 100 microseconds and a time interval between two consecutive power pulses T2 of 1 second. It will be appreciated that these values are only exemplary and may change. As long as no aerosol-generating article has been inserted, the control circuitry determines for each pulse from the ratio of the determined DC current to the determined DC voltage a conductance having a value G_NA (where the “NA” stands for “no article”). As explained above, the value of the conductance G_NA is a function of the ohmic load 114 when no article is present, that is, a function basically depending on the ohmic resistance of the inductor L2 only. In contrast, when user inserts an aerosol-generating article into the cavity 103, the ohmic load 114 is increased, since now the ohmic load equals the ohmic resistance of the inductor L2 and the ohmic resistance of the susceptor 21. Due to the increase of the ohmic load the conductance of the heating arrangement 110 decreases to a value of G_A (where the “A” stands for “article inserted”) which is lower than G_NA.

Yet, instead of detecting the change of the conductance, the present invention suggest to compare the determined value G of the conductance with a predetermined threshold value which is chosen such as to be between the values G_NA and G_A in order to reliably allow for distinguishing between an article 10 being present in the cavity 103 and an article being absent from the cavity 103. That is, the control circuitry is configured to detect the insertion of an article 10 into the cavity 103 or the extraction of an article 10 from the cavity 103 in response to the determined value G of conductance (determined for each power pulse) having breached the predetermined threshold value G_threshold. Advantageously, determining the value G of the conductance and comparing it with a predetermined threshold value G_threshold, which does not originate from an instant measurement, makes the article detection more reliable. In particular, this procedure avoids undesired false-positive or false-negative detection of the insertion or the extraction of an aerosol-generating article, for example, when an article is inserted into and extracted from the cavity only gradually or partially. Once detected, the breach of the predetermined threshold value G_threshold may trigger the start of the heating mode.

While FIG. 4 shows the article insertion detection mode only, FIG. 5 shows both, the evolution of the conductance during the article insertion detection mode (see left half of FIG. 5) as well as during the article extraction detection mode (see right half of FIG. 5). For the article insertion detection mode, reference is made to the above description of FIG. 4. The evolution of the conductance during the article extraction detection mode is reversed. That is, during the article extraction detection mode the control circuitry determines for each pulse a conductance having a value of G_A as long as an aerosol-generating article 10 is still received in the cavity 103. As soon as the article 10 is extracted from the cavity 103, the ohmic load 114 is decreased which causes the conductance of the heating assembly to increase. Accordingly, the control circuitry determines a conductance having a value G_NA which is above the predetermined threshold value G_threshold, thus indicating the extraction or absence of the article 10 from the cavity 103.

In general, the predetermined threshold value may be a predefined function of a reference value of the property of the inductive heating arrangement being (pre)determined when an aerosol-generating article is absent from the cavity. In the present embodiment, the threshold value G_threshold is a linear function of the reference value G_ref of the conductance being (pre)determined when an article 10 is absent from the cavity 103. It has been found that a threshold value G_threshold being, for example, 6 percent smaller than the reference value G_ref is appropriate to reliably distinguish between an article 10 being present in the cavity 103 and an article being absent from the cavity 103. Accordingly, the linear function describing the dependency of the threshold value G_threshold from the reference value G_ref for this specific example reads: G_threshold=0.94×G_ref. In other words, the threshold value G_threshold corresponds to the reference value G_ref of the conductance being (pre)determined when an article 10 is absent from the cavity 103 minus an offset of 6 percent of the reference value G_ref.

Preferably, the reference value G_ref of the conductance is predetermined and stored in the control circuitry during the manufacturing of the aerosol-generating device 100. For this, the device 100 may be calibrated at the manufacturing state, for example, without an article 10 being present in the cavity 103. Calibration may be accomplished by operating the device 100 such that the control circuitry generates one or more pulses for intermittently powering on the inductive heating arrangement 110. During the one or more pulses, the control circuit determines the value of the conductance which defines the reference value G_ref of the conductance for an article being absent from the cavity. This reference value G_ref is used to determine the threshold value G_threshold based on the predefined function stored in the control circuitry. The thus determined threshold value G_threshold in turn may be stored in the device in order to be available later during normal user operation for a comparison with a value of the conductance.

Advantageously, the reference value G_ref of the conductance is updated at predefined regular intervals during the lifetime of the aerosol-generating device 10. This procedure may help to counteract possible drifts (decrease or increase) of the conductance which may occur during the lifetime of the device 10, in particular due to drifts of the electrical parameters of the heating arrangement 110. This drift behavior is exemplary illustrated in FIG. 6 which shows the measured values G_NA and G_A of the conductance (closed continuous lines) over time t in units of months. As can been seen, both values gradually decrease over time. Only after a few days of operation the value G_NA of the conductance—when no article is present in the cavity—may have become even smaller than the threshold value G_threshold (dashed-dotted line) which is determined on the basis of the initial reference value G_ref (dashed line) having been measured and stored in the device at the manufacturing state (as indicated by arrow 999). As a result, the control circuitry would always return a value of the conductance being interpreted as indicating that an article 10 is present in the cavity 103, even in case it is not. Hence, the device 100 would be no longer capable of reliably detecting the insertion or extraction of an article 10 into the cavity 103. To compensate the observed drift behavior, the reference value of the conductance is updated at least every tenth time, preferably every time after a user experience, by redetermining during one or more power pulses the value of the conductance when no article 10 is present in the cavity, and by storing the redetermined value in the control circuitry as updated reference value G_ref*. The updated reference value G_ref* basically corresponds to the value G_NA determined during the article insertion detection mode or article extraction detection mode of the previous user experience cycle. The updated and stored reference value G_ref* may subsequently be used to update the threshold value G_threshold*, which in turn may then be used during the article insertion detection mode or article extraction detection mode of the next user experience cycle to determine whether an aerosol-generating article 10 is present in or absent from a cavity 103 of the device 100.

For the purpose of the present description and of the appended claims, except where otherwise indicated, all numbers expressing amounts, quantities, percentages, and so forth, are to be understood as being modified in all instances by the term “about”. Also, all ranges include the maximum and minimum points disclosed and include any intermediate ranges therein, which may or may not be specifically enumerated herein. In this context, therefore, a number A is understood as A±5 percent A. Within this context, a number A may be considered to include numerical values that are within general standard error for the measurement of the property that the number A modifies. The number A, in some instances as used in the appended claims, may deviate by the percentages enumerated above provided that the amount by which A deviates does not materially affect the basic and novel characteristic(s) of the claimed invention. Also, all ranges include the maximum and minimum points disclosed and include any intermediate ranges therein, which may or may not be specifically enumerated herein.

1.-20. (canceled)

21. An aerosol-generating device for heating an aerosol-forming substrate to form an inhalable aerosol when heated, the aerosol-generating device comprising:
a cavity configured to removably receive at least a portion of an aerosol-generating article, the aerosol-generating article including the aerosol-forming substrate and an inductively heatable susceptor configured to heat the substrate;
an inductive heating arrangement configured to generate an alternating magnetic field within the cavity for inductively heating the inductively heatable susceptor of the aerosol-generating article when the aerosol-forming article is received in the cavity; and
a control circuitry configured to generate power pulses for intermittently powering on the inductive heating arrangement, to determine during one or more power pulses a value of at least one property of the inductive heating arrangement, the value depending on an article with a susceptor being present in or absent from the cavity, and to detect at least one of the insertion of the article into the cavity or the extraction of the article from the cavity based on the determined value and a predetermined threshold value.

22. The aerosol-generating device according to claim 21, wherein the predetermined threshold value is a predefined function of a reference value of the at least one property of the inductive heating arrangement predetermined when the aerosol-generating article comprising the inductively heatable susceptor is absent from or present in the cavity.

23. The aerosol-generating device according to claim 22, wherein the predetermined threshold value corresponds to the reference value of the at least one property of the inductive heating arrangement, predetermined when the aerosol-generating article comprising the inductively heatable susceptor is absent from or present in the cavity, times a predefined scaling factor.

24. The aerosol-generating device according to claim 23, wherein the predefined scaling factor is in a range between 0.8 and 0.98.

25. The aerosol-generating device according claim 22, wherein the predetermined threshold value corresponds to the reference value of the at least one property of the inductive heating arrangement, predetermined when the aerosol-generating article comprising the inductively heatable susceptor is absent from or present in the cavity, plus or minus a predefined offset value.

26. The aerosol-generating device according to claim 25, wherein the offset value is in a range between 2 percent and 20 percent, of the predetermined reference value of the at least one property of the inductive heating arrangement.

27. The aerosol-generating device according to claim 22, wherein the reference value of the at least one property of the inductive heating arrangement is predetermined and stored in the control circuitry during the manufacturing of the aerosol-generating device.

28. The aerosol-generating device according to claim 22, wherein the reference value of the at least one property of the inductive heating arrangement is updated at predefined regular intervals during a lifetime of the aerosol-generating device.

29. The aerosol-generating device according to claim 28, wherein the reference value of the at least one property of the inductive heating arrangement is updated every tenth time after a user experience when the aerosol-generating article comprising the inductively heatable susceptor is absent from the cavity.

30. The aerosol-generating device according to claim 28, wherein the reference value of the at least one property of the inductive heating arrangement is updated by redetermining during one or more power pulses the at least one property of the inductive heating arrangement when the aerosol-generating article comprising the inductively heatable susceptor is absent from the cavity, and by storing a redetermined value in the control circuitry as an updated reference value.

31. The aerosol-generating device according to claim 21, wherein the predetermined threshold value is between a value of the at least one property being measured when the aerosol-generating article is present in the cavity and a value of the at least one property being measured when no aerosol-generating article is present in the cavity.

32. The aerosol-generating device according to claim 21, wherein the at least one property of the inductive heating arrangement is one of a current, a voltage, an electrical resistance, an electrical conductance, a frequency, a phase shift, a flux, and an inductance of the inductive heating arrangement.

33. The aerosol-generating device according to claim 21, wherein the control circuitry comprises a measurement device configured to determine at least one of a current and a voltage indicative of the at least one property of the inductive heating arrangement.

34. The aerosol-generating device according to claim 21,
wherein the control circuitry comprises a current measurement device configured to determine a DC current drawn by the inductive heating arrangement from a DC power supply of the device, and a voltage measurement device configured to determine a DC voltage supplied to the inductive heating arrangement by the DC power supply, and
wherein the control circuitry is further configured to determine a value of an electrical conductance of the inductive heating arrangement from a ratio of the determined DC current to the determined DC voltage.

35. An aerosol-generating system comprising an aerosol-generating device according to claim 21 and an aerosol-generating article for the aerosol-generating device, wherein at least a portion of the aerosol-generating article is removably receivable or removably received in the cavity of the aerosol-generating device, and wherein the aerosol-generating article comprises an aerosol-forming substrate and an inductively heatable susceptor configured to heat the substrate, when the aerosol-generating article is received in the cavity.

36. A method for detecting whether an aerosol-generating article having an inductively heatable susceptor is present in or absent from a cavity of an aerosol-generating device, wherein the aerosol-generating device comprises a cavity configured to removably receive at least a portion of the aerosol-generating article, an inductive heating arrangement configured to generate an alternating magnetic field within the cavity to inductively heat the inductively heatable susceptor of the aerosol-generating when the aerosol-generating article is received in the cavity, the method comprising:
determining, during one or more power pulses of the inductive heating arrangement, a value of at least one property of the inductive heating arrangement, the value depending on an article with a susceptor being present in or absent from the cavity; and
detecting at least one of an insertion of the article into the cavity or an extraction of the article from the cavity based on the determined value and a predetermined threshold value.

37. The method according to claim 36, wherein the predetermined threshold value is a predefined function of a reference value of the at least one property of the inductive heating arrangement predetermined when an aerosol-generating article comprising a susceptor is absent from or present in the cavity.

38. The method according to claim 37,
wherein the predetermined threshold value corresponds to the reference value of the at least one property of the inductive heating arrangement, predetermined when an aerosol-generating article comprising a susceptor is absent from or present in the cavity, times a predefined scaling factor, wherein the predefined scaling factor is in a range between 0.8 and 0.98, or wherein the predefined scaling factor is in a range between 1.02 and 1.2, or
wherein the predetermined threshold value corresponds to the reference value of the at least one property of the inductive heating arrangement, predetermined when an aerosol-generating article comprising a susceptor is absent from or present in the cavity, plus or minus a predefined offset value, wherein the predefined offset value is in a range between 2 percent and 20 percent, of the predetermined reference value of the at least one property of the inductive heating arrangement.

39. The method according to claim 37, wherein the reference value of the at least one property of the inductive heating arrangement is updated at predefined regular intervals during a lifetime of the aerosol-generating device.

40. The method according to claim 36, wherein the predetermined threshold value is between a value of the at least one property being measured when the aerosol-generating article is present in the cavity and a value of the at least one property being measured when no aerosol-generating article is present in the cavity.
